(19) United States
(12) Patent Application Publication
(10) Pub. No.: US 2024/0057327 A1
(43) Pub. Date: Feb. 15, 2024

(54) THREE-DIMENSIONAL FLASH MEMORY INCLUDING CHANNEL LAYER HAVING MULTILAYER STRUCTURE, AND METHOD FOR MANUFACTURING SAME

(71) Applicant: IUCF-HYU (Industry University Cooperation Foundation Hanyang University), Seoul (KR)

(72) Inventors: Yun Heub Song, Seoul (KR); Jae Kyung Jung, Seoul (KR)

(73) Assignee: IUCF-HYU (Industry University Cooperation Foundation Hanyang University), Seoul (KR)

(21) Appl. No.: 18/260,859

(22) PCT Filed: Nov. 25, 2021
(86) PCT No.: PCT/KR2021/017522

§ 371 Date: Aug. 2, 2023

(30) Foreign Application Priority Data
Jan. 11, 2021 (KR) 10-2021-0003124
Mar. 26, 2021 (KR) 10-2021-0039690

(51) Int. Cl. H10B 41/27; H01L 29/66; H01L 29/12

(52) U.S. Cl. CPC H10B 41/27; H01L 29/66825; H01L 29/122

(57) ABSTRACT

Disclosed are: a three-dimensional flash memory including a channel layer having a multilayer structure; and a method for manufacturing same. The channel layer has a dual structure including a first channel layer which is formed to be in contact with a charge storage layer and improves the electron mobility in an inversion region that is a contact interface with the charge storage layer, and a second channel layer formed on an inner wall of the first channel layer. Alternatively, the channel layer can have a dual structure including an outer first channel layer and a second channel layer formed on an inner wall of the first channel layer, wherein a heterojunction is formed as a junction between the first channel layer and the second channel layer.

### TECHNICAL FIELD

The following embodiments relate to a three-dimensional flash memory, and more particularly, to a technology for improving an electron mobility in a cell string.

### BACKGROUND ART

Flash memory elements are electrically erasable programmable read only memories (EEPROMs), and the memories may be commonly used in, for example, computers, digital cameras, MP3 players, game systems, memory sticks, and the like. Such flash memory elements electrically control input/output of data by Fowler-Nordheim tunneling or hot electron injection.

In detail, referring to FIG. 1 illustrating an array of a three-dimensional flash memory according to the related art, the array of the three-dimensional flash memory may include a common source line CSL, a bit line BL, and a plurality of cell strings CSTR arranged between the common source line CSL and the bit line BL.

The bit lines are two-dimensionally arranged, and the plurality of cell strings CSTR are connected in parallel to the bit lines. The cell strings CSTR may be commonly connected to the common source line CSL. That is, the plurality of cell strings CSTR may be arranged between the plurality of bit lines and the one common source line CSL. In this case, a plurality of common source lines CSL may be provided, and the plurality of common source lines CSL may be arranged two-dimensionally. Here, electrically the same voltage may be applied to the plurality of common source lines CSL or each of the common source lines CSL may be also electrically controlled.

Each of the cell strings CSTR may include a ground selection transistor GST connected to the common source line CSL, a string selection transistor SST connected to the bit line BL, and a plurality of memory cell transistors MCT arranged between the ground and string selection transistors GST and SST. Further, the ground selection transistor GST, the string selection transistor SST, and the memory cell transistors MCT may be connected in series.

The common source line CSL may be commonly connected to sources of the ground selection transistors GST. In addition, a ground selection line GSL, a plurality of word lines WL0 to WL3, and a plurality of string selection lines SSL, which are arranged between the common source line CSL and the bit line BL, may be used as electrode layers of the ground selection transistor GST, the memory cell transistors MCT, and the string selection transistors SST. Further, each of the memory cell transistors MCT includes a memory element. Hereinafter, the string selection line SSL may be expressed as an upper selection line USL, and the ground selection line GSL may be expressed as a lower selection line LSL.

Meanwhile, in a three-dimensional flash memory according to the related art, in order to satisfy excellent performance and low price required by consumers, cells are vertically stacked, and thus the degree of integration increases.

For example, referring to FIG. 2 illustrating a structure of the three-dimensional flash memory according to the related art, the three-dimensional flash memory according to the related art is manufactured by arranging an electrode structure 215, in which interlayer insulating layers 211 and horizontal structures 250 are alternately and repeatedly formed, on a substrate 200. The interlayer insulating layers 211 and the horizontal structures 250 may extend in a first direction. The interlayer insulating layers 211 may be, for example, a silicon oxide film, and the lowermost interlayer insulating layer 211a among the interlayer insulating layers 211 may have a thickness lower than those of the other interlayer insulating layers 211. Each of the horizontal structures 250 may include first and second blocking insulating films 242 and 243 and an electrode layer 245. A plurality of the electrode structures 215 are provided, and the plurality of electrode structures 215 may be arranged to face each other in a second direction intersecting the first direction. The first and second directions may correspond to an X axis and a Y axis of FIG. 2, respectively. Trenches 240 spacing the plurality of electrode structures 215 apart from each other may extend between the plurality of electrode structures 215 in the first direction. Highly doped impurity areas may be formed in the substrate 200 exposed by the trenches 240, and thus the common source line CSL may be disposed. Although not illustrated, isolation insulating films filling the trenches 240 may be further arranged.

Vertical structures 230 passing through the electrode structures 215 may be arranged. As an example, in a plan view, the vertical structures 230 may be arranged in a matrix form while being aligned in the first and second directions. As another example, the vertical structures 230 may be aligned in the second direction and may be arranged in a zigzag form in the first direction. Each of the vertical structures 230 may include a protective film 224, a charge storage film 225, a tunnel insulating film 226, and a channel layer 227. As an example, the channel layer 227 may be disposed in a hollow tube shape therein, and in this case, a buried film 228 (formed as an oxide) filling an inside of the channel layer 227 may be further disposed. A drain area D may be disposed on the channel layer 227 and a conductive pattern 229 may be formed on the drain area D and may be connected to the bit line BL. The bit line BL may extend in a direction intersecting the horizontal electrodes 250, for example, in the second direction. As an example, the vertical structures 230 aligned in the second direction may be connected to the one bit line BL.

The first and second blocking insulating films 242 and 243 included in the horizontal structures 250 and the charge storage film 225 and the tunnel insulating film 226 included in the vertical structures 230 may be defined as oxide-nitride-oxide (ONO) layers that are information storage elements of the three-dimensional flash memory. That is, some of the information storage elements may be included in the vertical structures 230, and the other thereof may be included in the horizontal structures 250. As an example, among the information storage elements, the charge storage film 225 and the tunnel insulating film 226 may be included in the vertical structures 230, and the first and second blocking insulating films 242 and 243 may be included in the horizontal structures 250.

Epitaxial patterns 222 may be arranged between the substrate 200 and the vertical structures 230. The epitaxial patterns 222 connect the substrate 200 and the vertical structures 230. The epitaxial patterns 222 may be in contact with at least one layer of the horizontal structures 250. That is, the epitaxial patterns 222 may be arranged in contact with a lowermost horizontal structure 250a. According to another embodiment, the epitaxial patterns 222 may be arranged in contact with a plurality of layers, for example, two layers, of the horizontal structures 250. Meanwhile, when the epitaxial patterns 222 are arranged in contact with the lowermost horizontal structure 250a, the lowermost horizontal structure 250a may be thicker than the other horizontal structures 250. The lowermost horizontal structure 250a in contact with the epitaxial patterns 222 may correspond to the ground selection line GSL of the array of the three-dimensional flash memory described with reference to FIG. 1, and the other horizontal structures 250 in contact with the vertical structures 230 may correspond to the plurality of word lines WL0 to WL3.

Each of the epitaxial patterns 222 has a recessed side wall 222a. Accordingly, the lowermost horizontal structure 250a in contact with the epitaxial patterns 222 is disposed along a profile of the recessed side wall 222a. That is, the lowermost horizontal structure 250a may be disposed in an inwardly convex shape along the recessed side walls 222a of the epitaxial patterns 222.

In the three-dimensional flash memory having such a structure according to the related art, polycrystalline silicon is used as the channel layer 227. However, since the polycrystalline silicon has a very low actual electron mobility due to grain boundary effects, the three-dimensional flash memory according to the related art does not satisfy the demand for an electron mobility according to a length of the highly stepped channel layer 270, and thus degradation of memory performance, such as a decrease in an operation speed, occurs.

Thus, it is required to propose a technology for solving the electron mobility problem of the three-dimensional flash memory according to the related art.

### DETAILED DESCRIPTION OF THE INVENTION

### Technical Problem

Embodiments propose a three-dimensional flash memory including a channel layer having a double structure to improve an electron mobility in the channel layer, and a method of manufacturing the same.

However, technical problems to be solved by the present disclosure are not limited to the above problems and may be variously expanded without departing from the technical spirit and scope of the present disclosure.

### Technical Solution

According to an embodiment, a three-dimensional flash memory includes a plurality of word lines extending on a substrate in a horizontal direction and sequentially stacked, and at least one cell string passing through the plurality of word lines and extending on the substrate in a vertical direction, the at least one cell string including a channel layer extending in the vertical direction and a charge storage layer formed to surround the channel layer, wherein the channel layer has a double structure including a first channel layer for improving an electron mobility in an inversion area that is a contact interface with the charge storage layer while the first channel layer is formed in contact with the charge storage layer and a second channel layer on an inner wall of the first channel layer.

According to an aspect, the first channel layer may be formed of a material having a higher electron mobility than that of the second channel layer or a higher electron mobility than a threshold value to improve the electron mobility in the inversion area that is a contact interface with the charge storage layer.

According to another aspect, the first channel layer may be formed of any one of a polycrystalline group 3-5 compound (poly 3-5) or polycrystalline silicon germanium (poly Si—Ge).

According to still another aspect, the second channel layer may be used as a protection layer or an electron transfer assist layer for the first channel layer.

According to yet another aspect, the second channel layer may be formed of a material having more excellent durability and thermal performance than those of the first channel layer.

According to yet another aspect, the second channel layer may be formed of polycrystalline silicon (Poly Si).

According to an embodiment, a method of manufacturing a three-dimensional flash memory includes preparing a semiconductor structure including a plurality of word lines extending on a substrate in a horizontal direction and sequentially stacked and at least one hole passing through the plurality of word lines and extending on the substrate in a vertical direction, forming a charge storage layer including an inner hole in the at least one hole of the semiconductor structure, and extending a channel layer having a double structure in the vertical direction inside the inner hole, wherein the extending of the channel layer includes forming a first channel layer for improving an electron mobility in an inversion area that is a contact interface with the charge storage layer such that the first channel layer is in contact with the charge storage layer, and forming a second channel layer in an inner wall of the first channel layer.

According to another embodiment, a method of manufacturing a three-dimensional flash memory includes preparing a semiconductor structure including a plurality of sacrificial layers extending on a substrate in a horizontal direction and sequentially stacked and at least one hole passing through the plurality of sacrificial layers and extending on the substrate in a vertical direction, forming a charge storage layer including an inner hole in the at least one hole of the semiconductor structure, extending a channel layer having a double structure in the vertical direction inside the inner hole, removing the plurality of sacrificial layers, and forming a plurality of word lines in spaces from which the plurality of sacrificial layers are removed, wherein the extending of the channel layer includes forming a first channel layer for improving an electron mobility in an inversion area that is a contact interface with the charge storage layer such that the first channel layer is in contact with the charge storage layer, and forming a second channel layer in an inner wall of the first channel layer.

According to an embodiment, a three-dimensional flash memory includes a plurality of word lines extending on a substrate in a horizontal direction and sequentially stacked, and at least one string passing through the plurality of word lines and extending on the substrate in a vertical direction, the at least one string including a channel layer extending in the vertical direction and a charge storage layer formed to surround the channel layer, wherein while the channel layer has a double structure including an outer first channel layer and a second channel layer formed in an inner wall of the first channel layer, a heterojunction is formed as a junction between the first channel layer and the second channel layer.

According to an aspect, the first channel layer and the second channel layer may be formed of a metal oxide so that the heterojunction is formed as the junction between the first channel layer and the second channel layer.

According to another aspect, the first channel layer and the second channel layer may be formed of a metal oxide including at least one of In, Zn, or Ga or a metal oxide including a group 4 semiconductor material.

According to still another aspect, the first channel layer and the second channel layer may be formed of different materials among the metal oxides.

According to yet another aspect, the three-dimensional flash memory may implement a quantum well through the heterojunction to improve an electron mobility in the junction between the first channel layer and the second channel layer.

According to an embodiment, a method of manufacturing a three-dimensional flash memory includes preparing a semiconductor structure including a plurality of word lines extending on a substrate in a horizontal direction and sequentially stacked, and at least one string passing through the plurality of word lines and extending on the substrate in a vertical direction, the at least one string including a channel layer extending in the vertical direction and a charge storage layer formed to surround the channel layer, forming an N+ doped part at an upper end of the at least one string, and generating at least one wiring line in contact with the N+ doped part, wherein the preparing of the semiconductor structure includes implementing the channel layer through a double structure including an outer first channel layer and a second channel layer formed on an inner wall of the first channel layer so that a heterojunction is formed as a junction between the first channel layer and the second channel layer.

### Advantageous Effects of the Invention

Embodiments propose a three-dimensional flash memory including a channel layer having a double structure and a method of manufacturing the same, so that an electron mobility in the channel layer may be improved, and thus an operation speed and memory performance may be improved.

However, effects of the present disclosure are not limited to the above effects and may be variously expanded without departing from the technical spirit and scope of the present disclosure.

### DESCRIPTION OF THE DRAWINGS

FIG. 1 is a schematic circuit diagram illustrating an array of a three-dimensional flash memory according to the related art;

FIG. 2 is a perspective view illustrating a structure of the three-dimensional flash memory according to the related art;

FIG. 3 is a side cross-sectional view illustrating a three-dimensional flash memory according to an embodiment;

FIG. 4 is a flowchart illustrating a method of manufacturing the three-dimensional flash memory according to the embodiment;

FIGS. 5A to 5E are side cross-sectional views illustrating the three-dimensional flash memory to describe the manufacturing method illustrated in FIG. 4;

FIG. 6 is a flowchart illustrating a method of manufacturing a three-dimensional flash memory according to another embodiment;

FIGS. 7A to 7G are side cross-sectional views illustrating the three-dimensional flash memory to describe the manufacturing method illustrated in FIG. 6;

FIG. 8 is a side cross-sectional view illustrating the three-dimensional flash memory according to the embodiment;

FIG. 9 is a flowchart illustrating a method of manufacturing the three-dimensional flash memory according to the embodiment; and

FIGS. 10A to 10E are side cross-sectional views illustrating the three-dimensional flash memory to describe the manufacturing method illustrated in FIG. 9.

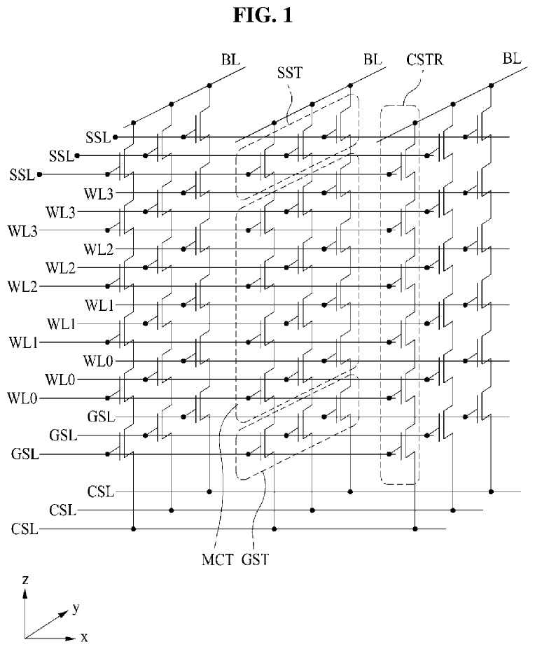

### BEST MODE

Hereinafter, embodiments of the present disclosure will be described in detail with reference to the accompanying drawing. However, the present disclosure is not restricted or limited by the embodiments. Further, the same reference numerals in each drawing indicate the same components.

Further, terms used in the present specification are used to properly express the embodiments of the present disclosure, and the terms may change depending on the intention of a viewer or an operator or customs in the field to which the present disclosure belongs. Therefore, definitions of the present terms should be made based on the contents throughout the present specification. For example, in the present specification, a singular form also includes a plural form unless specifically mentioned in a phrase. Further, the term “comprise” or “comprising” used herein does not exclude the presence or addition of one or more other components, steps, operations, and/or to components, steps, operations, and/or elements in or to components, steps, operations, and/or elements mentioned above.

Further, it should be understood that various embodiments of the present disclosure are different from each other but are not necessarily mutually exclusive. For example, specific shapes, specific structures, and specific characteristics described herein may be implemented in another embodiment without departing from the technical spirit and scope of the present disclosure in relation to an embodiment. Further, it should be understood that positions, arrangements, or configurations of individual components in the range of each presented embodiment may be changed without departing from the technical spirit and scope of the present disclosure.

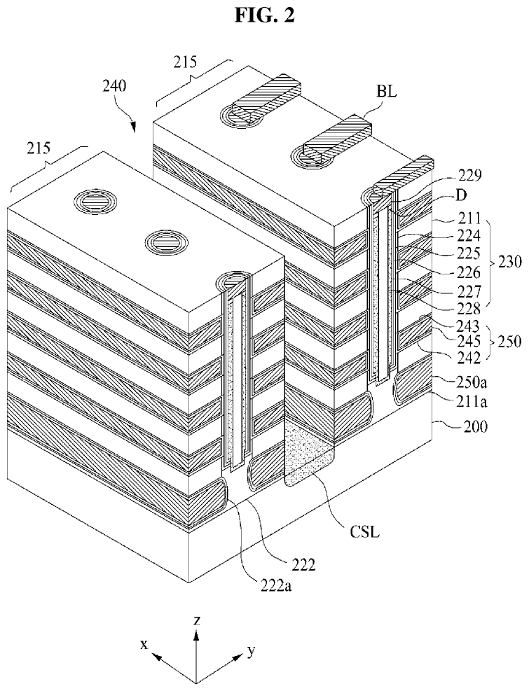

Hereinafter, in a side cross-sectional view illustrating a three-dimensional flash memory, for convenience of description, a three-dimensional flash memory will be illustrated and described while components such as a source line positioned below a plurality of cell strings are omitted. However, the three-dimensional flash memory, which will be described below, is not restricted and limited thereto, and may further include an additional component on the basis of a structure of the three-dimensional flash memory illustrated with reference to FIG. 2.

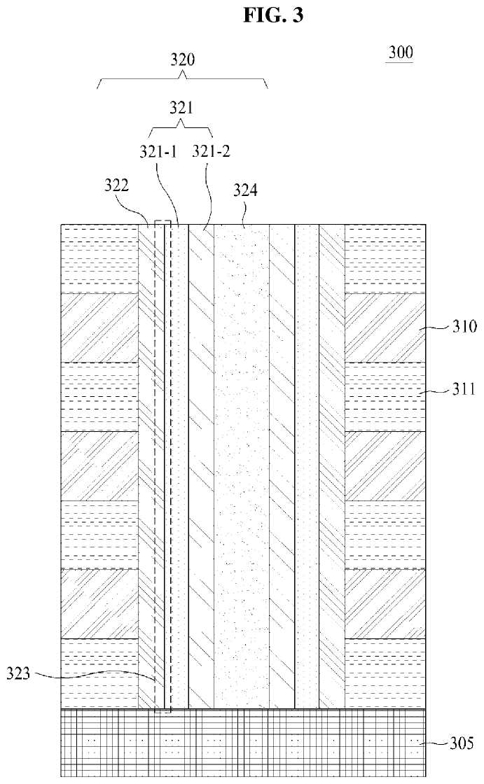

FIG. 3 is a side cross-sectional view illustrating the three-dimensional flash memory according to the embodiment.

Referring to FIG. 3, a three-dimensional flash memory 300 according to the embodiment includes a plurality of word lines 310 and at least one cell string 320.

The plurality of word lines 310 are sequentially stacked in a vertical direction while extending on a substrate 305 in a horizontal direction, are made of a conductive material such as W (tungsten), Ti (titanium), Ta (tantalum), Cu (copper), Mo (molybdenum), Ru (ruthenium), or Au (gold) (including all metallic materials capable of forming ALD in addition to the above-described metallic materials), apply voltages to memory cells corresponding thereto, and perform a memory operation (a reading operation, a program operation, an erasure operation, or the like). A plurality of insulating layers 311 made of an insulating material may be interposed between the plurality of word lines 310.

A string selection line SSL may be disposed at a top of the plurality of word lines 310, and a ground selection line GSL may be disposed at a bottom thereof.

The at least one cell string 320 passes through the plurality of word lines 310, extends on the substrate 305 in a vertical direction, includes a channel layer 321 and a charge storage layer 322, and thus may constitute a plurality of memory cells corresponding to the plurality of word lines 310.

The charge storage layer 322 is a component that traps charges or holes by voltages applied through the plurality of word lines 310 or maintains states of charges (e.g., polarization states of charges) while extending to surround the channel layer 321 and may serve as a data storage in the three-dimensional flash memory 300. As an example, an ONO layer or a ferroelectric layer may be used as the charge storage layer 322. The charge storage layer 322 is not restricted or limited to the extending to surround the channel layer 321 and may also have a structure in which the charge storage layer 322 is separated for each memory cell while surrounding the channel layer 321.

The channel layer 321 may be a component that performs a memory operation by voltages applied through the plurality of word lines 310, the SSL, the GSL, and the bit line and may have a double structure including an outer first channel layer 321-1 formed in contact with the charge storage layer 322 and a second channel layer 321-2 formed on an inner wall of the first channel layer 321-1.

The first channel layer 321-1 among the channel layer 321 having the double structure serves to improve an electron mobility in an inversion area 323 that is a contact interface with the charge storage layer 322. To this end, the first channel layer 321-1 may be formed of a material having a higher electron mobility than that of the second channel layer 321-2 or a higher electron mobility than a threshold value (hereinafter, the threshold value refers to an effective value for achieving an electron mobility required in the three-dimensional flash memory 300). As an example, the first channel layer 321-1 may be formed of any one of a polycrystalline group 3-5 compound (poly 3-5) or polycrystalline silicon germanium (poly Si—Ge). Hereinabove, it has been described that the first channel layer 321-1 improves the electron mobility in the inversion area 323 that is a contact interface with the charge storage layer 322, but the present disclosure is not limited thereto, and the first channel layer 321-1 may improve the electron mobility in an entire area thereof.

On the other hand, the second channel layer 321-2 among the channel layer 321 having the double structure may be used as a protection layer or an electron transfer assist layer for the first channel layer 321-1. To this end, the second channel layer 321-2 may be formed of a material having greater durability and thermal performance than those of the first channel layer 321-1. As an example, the second channel layer 321-2 may be formed of polycrystalline silicon. However, the present disclosure is not limited thereto, and the second channel layer 321-2 may be formed of monocrystalline silicon.

Further, the second channel layer 321-2 may be formed of a material having excellent leakage current characteristics (e.g., a metal oxide including at least one of In, Zn, or Ga, or a metal oxide including a group 4 semiconductor material) and thus serve to block and suppress a leakage current in the first channel layer 321-1.

A buried film 324 may be formed inside the channel layer 321 having the double structure. As an example, the oxide buried film 324 may be formed in an inner space of the second channel layer 321-2 among the channel layer 321 having the double structure. However, the buried film 324 may be omitted according to the embodiment, and in this case, the second channel layer 321-2 may be formed in a cylindrical shape having a fully filled inside rather than a macaroni shape having an empty inside.

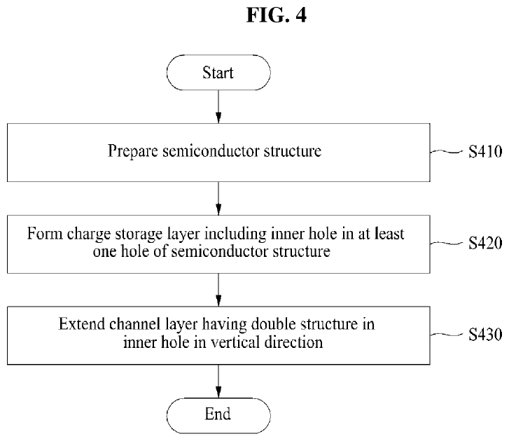

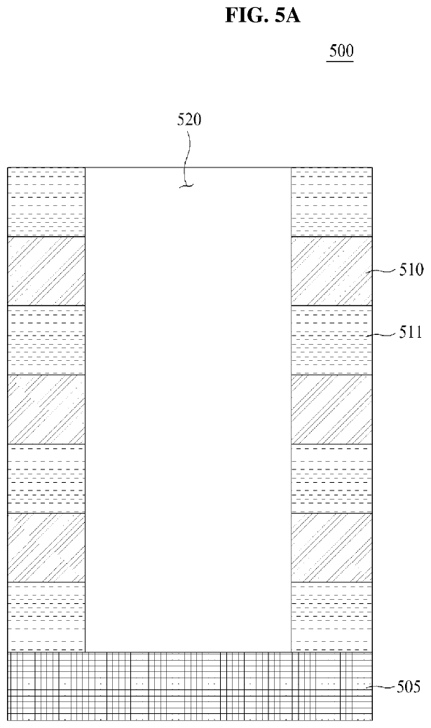

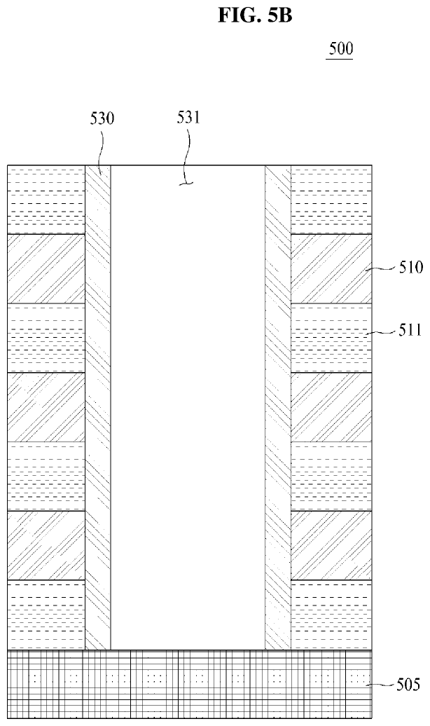

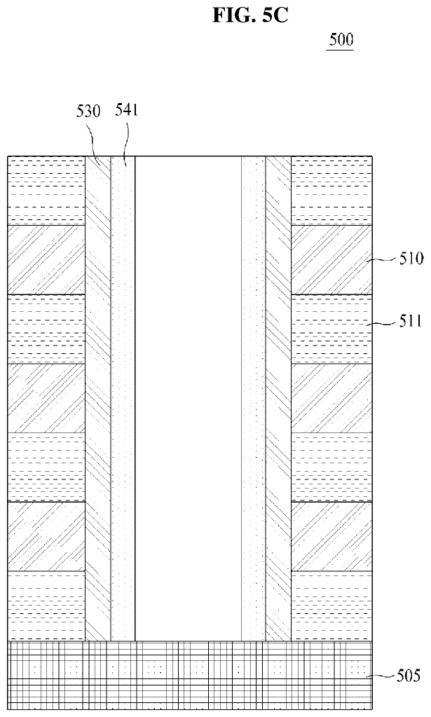

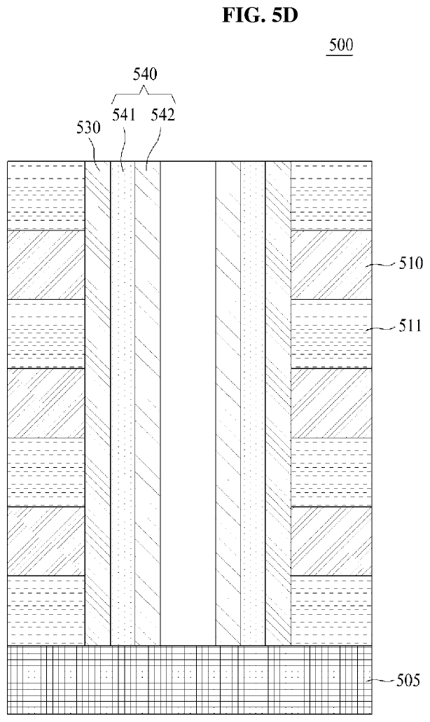

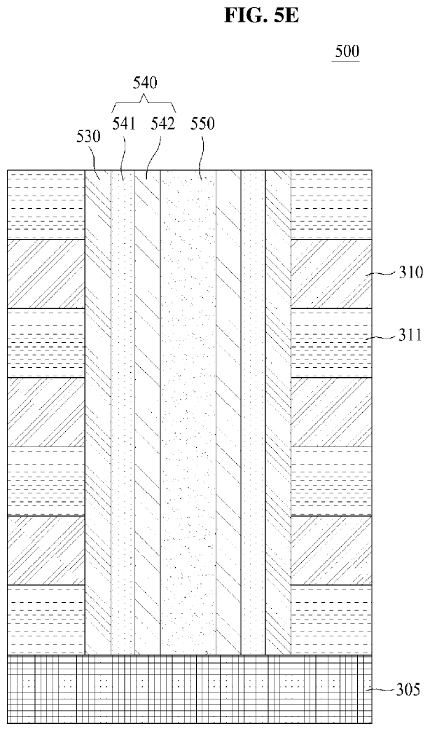

FIG. 4 is a flowchart illustrating a method of manufacturing the three-dimensional flash memory according to the embodiment, and FIGS. 5A to 5E are side cross-sectional views illustrating the three-dimensional flash memory to describe the manufacturing method illustrated in FIG. 4.

Hereinafter, the manufacturing method, which will be described below, is based on the premise that the manufacturing method is performed by an automated and mechanized manufacturing system, and the three-dimensional flash memory completely manufactured through the manufacturing method may have the structure described with reference to FIG. 3.

Referring to FIG. 4, in operation S410, a manufacturing system according to the embodiment may prepare a semiconductor structure 500 as in FIG. 5A.

Here, the semiconductor structure 500 may include a plurality of word lines 510 extending on a substrate 505 in a horizontal direction and sequentially stacked and at least one hole 520 passing through the plurality of word lines 510 and extending on the substrate 505 in a vertical direction. Further, a plurality of insulation layers 511 made of an insulating material may be interposed between the plurality of word lines 510.

Next, in operation S420, the manufacturing system may extend a charge storage layer 530 in a vertical direction, the charge storage layer 530 including an inner hole 531 inside the at least one hole 520 of the semiconductor structure 500 as in FIG. 5B.

Hereinabove, it has been described that the preparing of the semiconductor structure 500 and the extending of the charge storage layer 530 are performed as separate operations, but the present disclosure is not limited thereto, and the preparing of the semiconductor structure 500 and the extending of the charge storage layer 530 may be performed through one operation. For example, as the semiconductor structure 500 having the at least one hole 520 including the inner hole 531 is prepared in operation S410, the preparing of the semiconductor structure 500 and the extending of the charge storage layer 530 may be performed through one operation S410.

Thereafter, in operation S430, the manufacturing system may extend a channel layer 540 having a double structure in a vertical direction inside the inner hole 531 as in FIGS. 5C and 5D. In more detail, the manufacturing system may form a first channel layer 541 for improving an electron mobility in an inversion area that is a contact interface with the charge storage layer 530 as in FIG. 5C such that the first channel layer 541 is in contact with the charge storage layer 530, form a second channel layer 542 on an inner wall of the first channel layer 541 as in FIG. 5D, and thus form the channel layer 540 having a double structure.

In relation to the forming of the first channel layer 541, the manufacturing system may form the first channel layer 541 of a material having a higher electron mobility than that of the second channel layer 542 or a higher electron mobility than a threshold value to improve the electron mobility in the inversion area that is a contact interface with the charge storage layer 530. For example, the manufacturing system may form the first channel layer 541 of any one of a polycrystalline group 3-5 compound (poly 3-5) or polycrystalline silicon germanium (poly Si—Ge).

In relation to the forming of the second channel layer 542, the manufacturing system may form the second channel layer 542 of a material having more excellent durability and thermal performance than those of the first channel layer 541 so that the second channel layer 542 is used as a protection layer or an electron transfer assist layer for the first channel layer 541. For example, the manufacturing system may form the second channel layer 542 of polycrystalline silicon.

Further, although not illustrated as a separate operation, after operation S430, the manufacturing system may form a buried film 550 inside the channel layer 540 as in FIG. 5E. As an example, the manufacturing system may form the oxide buried film 550 inside the second channel layer 542. However, the present disclosure is not limited thereto, and in operation S430, the second channel layer 542 is formed in a cylindrical shape having a fully filled inside, and thus a process of forming the buried film 550 may be omitted.

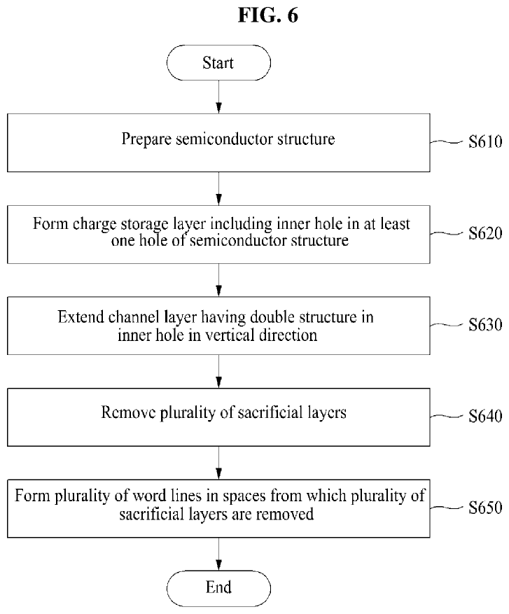

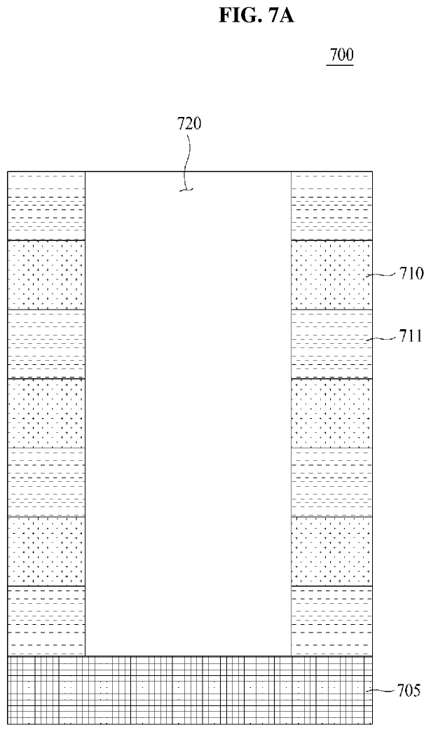

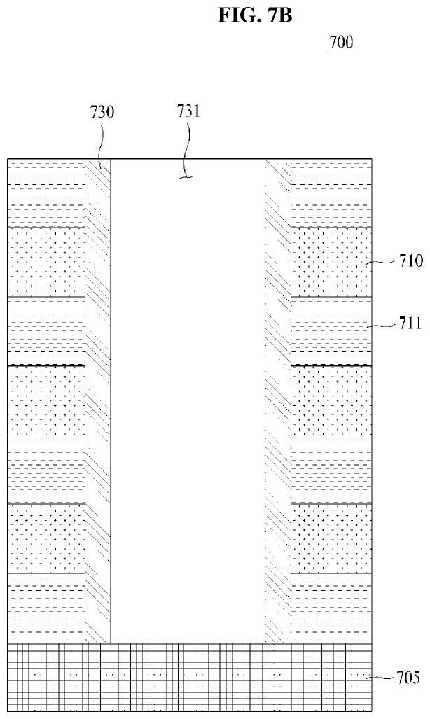

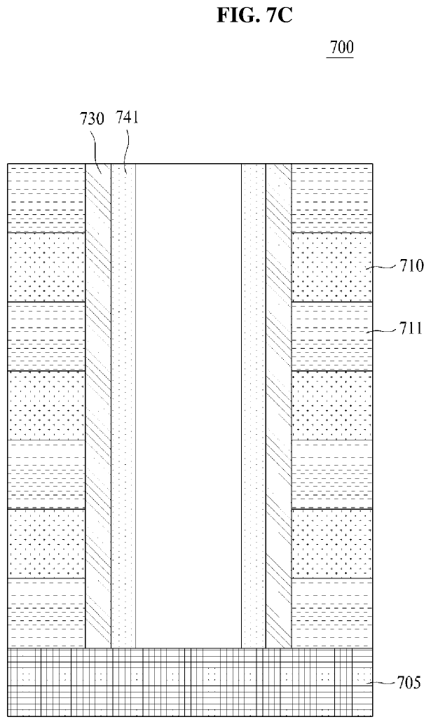

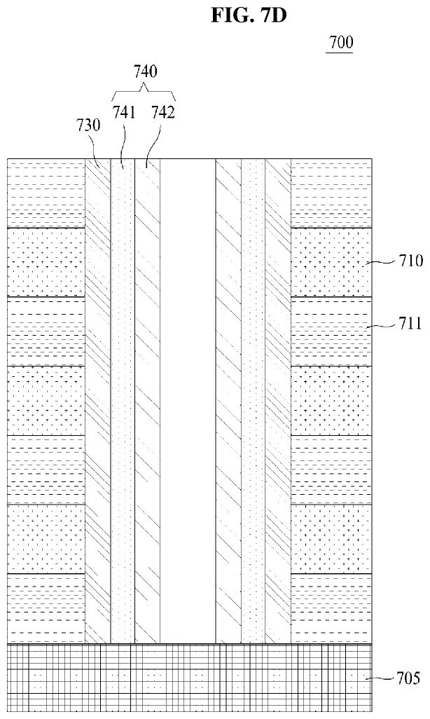

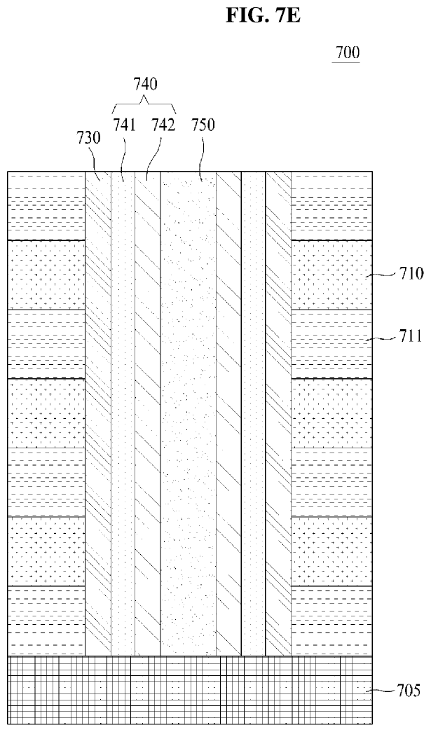

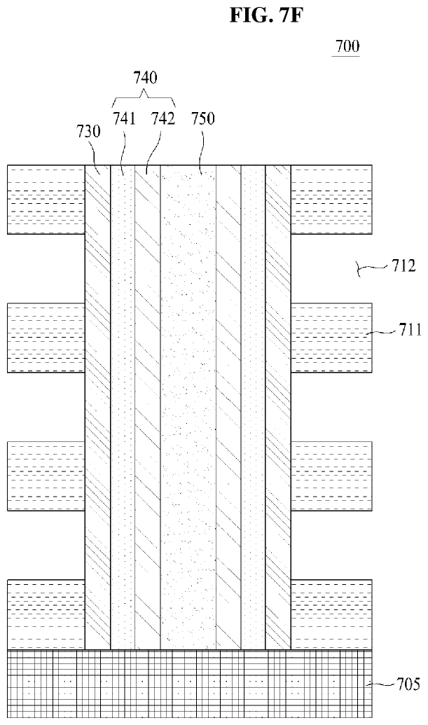

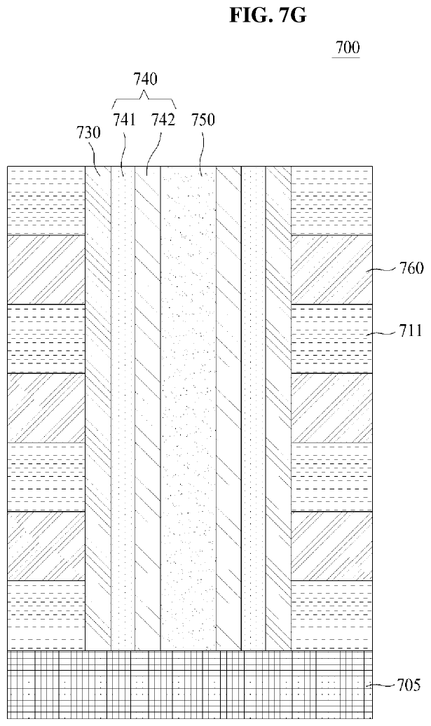

FIG. 6 is a flowchart illustrating a method of manufacturing a three-dimensional flash memory according to another embodiment, and FIGS. 7A to 7G are side cross-sectional views illustrating the three-dimensional flash memory to describe the manufacturing method illustrated in FIG. 6.

Hereinafter, the manufacturing method, which will be described below, is based on the premise that the manufacturing method is performed by an automated and mechanized manufacturing system, and the three-dimensional flash memory completely manufactured through the manufacturing method may have the structure described with reference to FIG. 3.

Referring to FIG. 6, in operation S610, a manufacturing system according to the embodiment may prepare a semiconductor structure 700 as in FIG. 7A.

Here, the semiconductor structure 700 may include a plurality of sacrificial lines 710 extending on a substrate 705 in a horizontal direction and sequentially stacked and at least one hole 720 passing through the plurality of sacrificial lines 710 and extending on the substrate 705 in a vertical direction. Further, a plurality of insulation layers 711 made of an insulating material may be interposed between the plurality of sacrificial lines 710.

Next, in operation S620, the manufacturing system may extend a charge storage layer 730 in a vertical direction, the charge storage layer 530 including an inner hole 731 inside the at least one hole 720 of the semiconductor structure 700 as in FIG. 7B.

Hereinabove, it has been described that the preparing of the semiconductor structure 700 and the extending of the charge storage layer 730 are performed as separate operations, but the present disclosure is not limited thereto, and the preparing of the semiconductor structure 700 and the extending of the charge storage layer 730 may be performed through one operation. For example, as the semiconductor structure 700 having the at least one hole 720 including the inner hole 731 is prepared in operation S610, the preparing of the semiconductor structure 700 and the extending of the charge storage layer 730 may be performed through one operation S610.

Next, in operation S630, the manufacturing system may extend a channel layer 740 having a double structure in a vertical direction inside the inner hole 731 as in FIGS. 7C and 7D. In more detail, the manufacturing system may form a first channel layer 741 for improving an electron mobility in an inversion area that is a contact interface with the charge storage layer 730 as in FIG. 7C such that the first channel layer 741 is in contact with the charge storage layer 730, form a second channel layer 742 on an inner wall of the first channel layer 541 as in FIG. 7D, and thus form the channel layer 740 having a double structure.

In relation to the forming of the first channel layer 741, the manufacturing system may form the first channel layer 741 of a material having a higher electron mobility than that of the second channel layer 742 or a higher electron mobility than a threshold value to improve the electron mobility in the inversion area that is a contact interface with the charge storage layer 730. For example, the manufacturing system may form the first channel layer 741 of any one of a polycrystalline group 3-5 compound (poly 3-5) or polycrystalline silicon germanium (poly Si—Ge).

In relation to the forming of the second channel layer 742, the manufacturing system may form the second channel layer 742 of a material having more excellent durability and thermal performance than those of the first channel layer 741 so that the second channel layer 742 is used as a protection layer or an electron transfer assist layer for the first channel layer 741. For example, the manufacturing system may form the second channel layer 742 of polycrystalline silicon.

Further, although not illustrated as a separate operation, after operation S630, the manufacturing system may form a buried film 750 inside the channel layer 740 as in FIG. 7E. As an example, the manufacturing system may form the oxide buried film 750 inside the second channel layer 742. However, the present disclosure is not limited thereto, and in operation S630, the second channel layer 742 is formed in a cylindrical shape having a fully filled inside, and thus a process of forming the buried film 750 may be omitted.

Next, in operation S640, as in FIG. 7F, the manufacturing system may remove the plurality of sacrificial layers 710.

Thereafter, in operation S650, the manufacturing system may form a plurality of word lines 760 in spaces 712 from which the plurality of sacrificial layers 710 are removed as in FIG. 7G.

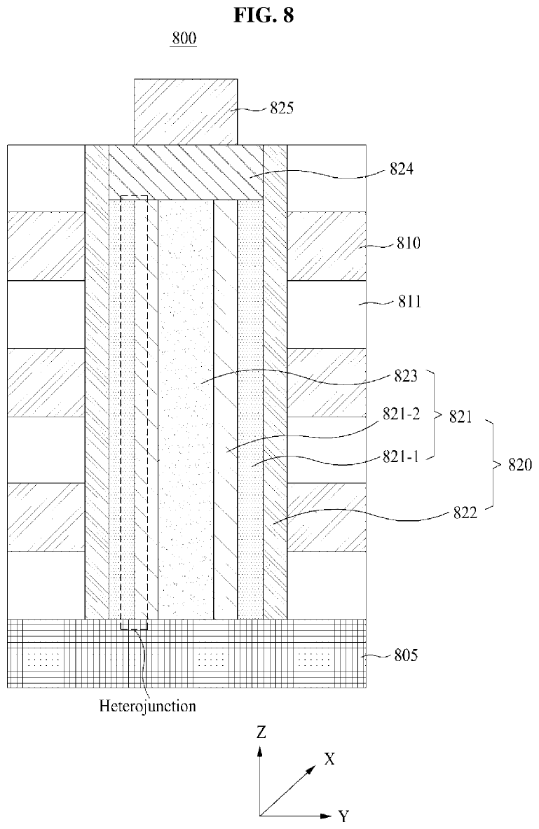

FIG. 8 is a side cross-sectional view illustrating the three-dimensional flash memory according to the embodiment.

Referring to FIG. 8, a three-dimensional flash memory 800 according to the embodiment includes a plurality of word lines 810 and at least one string 820.

The plurality of word lines 810 are sequentially stacked while extending on a substrate 805 in a horizontal direction, are made of a conductive material such as W (tungsten), Ti (titanium), Ta (tantalum), Cu (copper), Mo (molybdenum), Ru (ruthenium), or Au (gold) (including all metallic materials capable of forming ALD in addition to the above-described metallic materials), apply voltages to memory cells corresponding thereto, and perform a memory operation (a reading operation, a program operation, an erasure operation, or the like). A plurality of insulating layers 811 made of an insulating material may be interposed between the plurality of word lines 810.

An SSL may be disposed at a top of the plurality of word lines 810, and a GSL may be disposed at a bottom thereof.

The at least one string 820 passes through the plurality of word lines 810, extends on the substrate 805 in a vertical direction, includes a channel layer 821 and a charge storage layer 822, and thus may constitute a plurality of memory cells corresponding to the plurality of word lines 810.

The charge storage layer 822 is a component that traps charges or holes by voltages applied through the plurality of word lines 810 or maintains states of charges (e.g., polarization states of charges) while extending to surround the channel layer 821 and may serve as a data storage in the three-dimensional flash memory 800. As an example, an ONO layer or a ferroelectric layer may be used as the charge storage layer 822. The charge storage layer 822 is not restricted or limited to the extending to surround the channel layer 821 and may also have a structure in which the charge storage layer 822 is separated for each memory while surrounding the channel layer 821.

The channel layer 821 may be a component that performs a memory operation by voltages applied through the plurality of word lines 810, the SSL, the GSL, and the bit line and may have a double structure including an outer first channel layer 821-1 and a second channel layer 821-2 formed on an inner wall of the first channel layer 821-1.

In particular, in the channel layer 821 having a double structure, as a heterojunction is formed as a junction between the first channel layer 821-1 and the second channel layer 821-2, a quantum well is implemented using the heterojunction, and thus an electron mobility in the junction between the first channel layer 821-1 and the second channel layer 821-2 may be improved.

In this way, the first channel layer 821-1 and the second channel layer 821-2 may be formed of a metal oxide so that the heterojunction is formed as the junction between the first channel layer 821-1 and the second channel layer 821-2. For example, the first channel layer 821-1 and the second channel layer 821-2 may be formed of a metal oxide including at least one of In, Zn, or Ga or a metal oxide including a group 4 semiconductor material. However, the first channel layer 821-1 and the second channel layer 821-2 are not restricted or limited to being formed of the metal oxide described above and may be formed of various materials as long as the heterojunction may be formed as the junction between the first channel layer 821-1 and the second channel layer 821-2 through the materials.

In this case, the first channel layer 821-1 and the second channel layer 821-2 may be formed of different materials among metal oxides. For example, the first channel layer 821-1 may be formed of an IGZO material, and the second channel layer 821-2 may be formed of a ZnO material.

However, the first channel layer 821-1 and the second channel layer 821-2 are not restricted or limited to being formed of different materials among metal oxides and may be formed of the same material among metal oxides. For example, the first channel layer 821-1 and the second channel layer 821-2 may be formed of the IGZO material. However, in this case, a process of forming the first channel layer 821-1 and the second channel layer 821-2 of the same material may be adjusted so that the heterojunction may be formed as the junction between the first channel layer 821-1 and the second channel layer 821-2.

A buried film 823 may be formed inside the channel layer 821 having the double structure. As an example, the oxide buried film 823 may be formed in an inner space of the second channel layer 821-2 among the channel layer 821 having the double structure. However, the buried film 823 may be omitted according to the embodiment, and in this case, the second channel layer 821-2 may be formed in a cylindrical shape having a fully filled inside rather than a macaroni shape having an empty inside.

A N+ doped part 824 may be formed as a drain junction at an upper end of the at least one string 820. Accordingly, a wiring line 825 such as a drain line may be disposed above the N+ doped part 824.

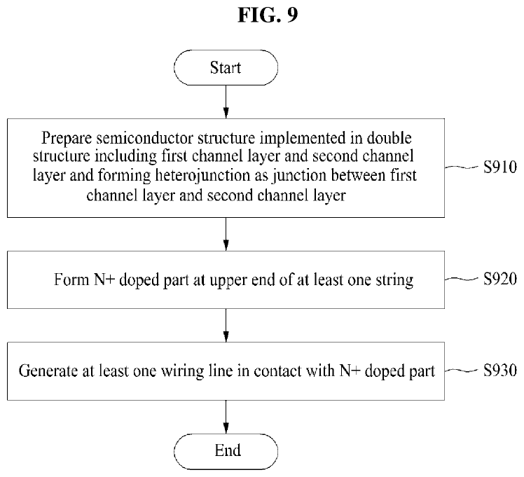

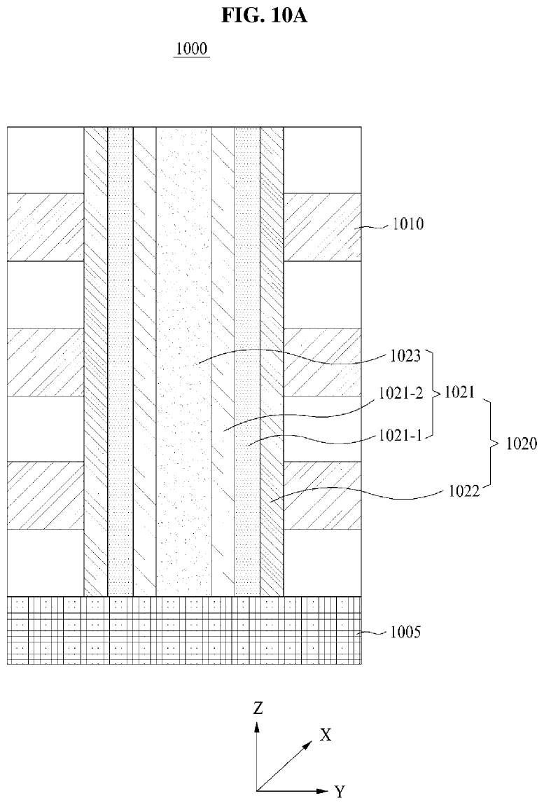

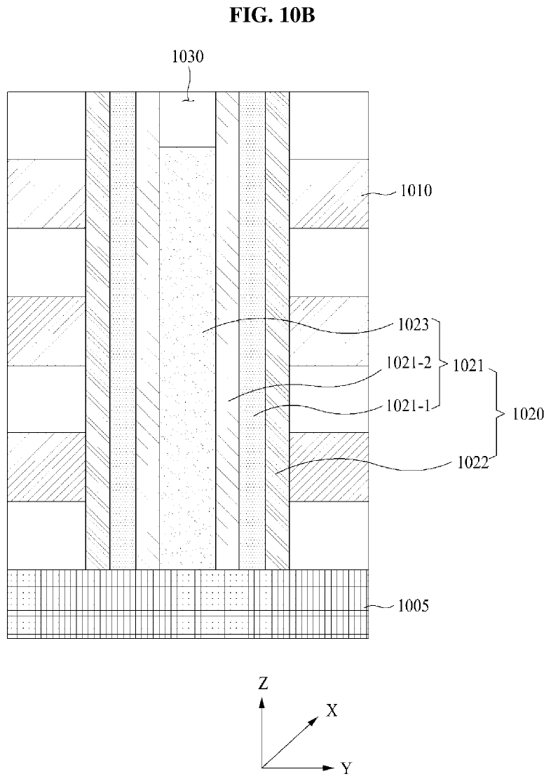

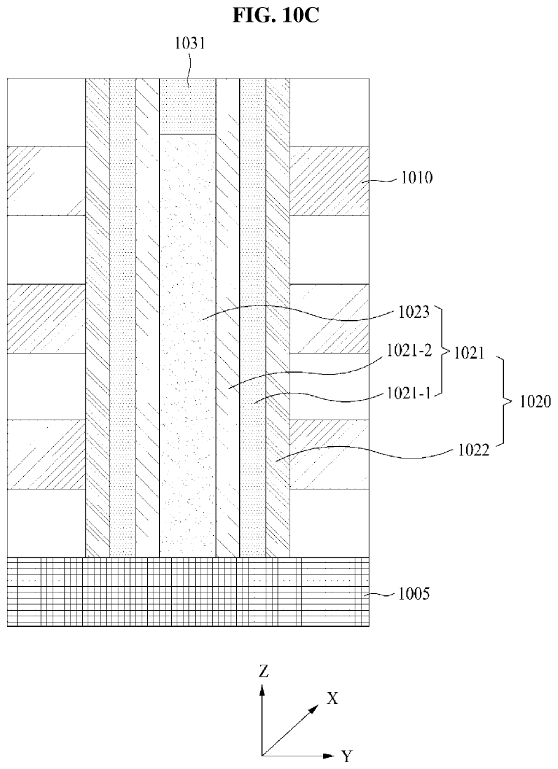

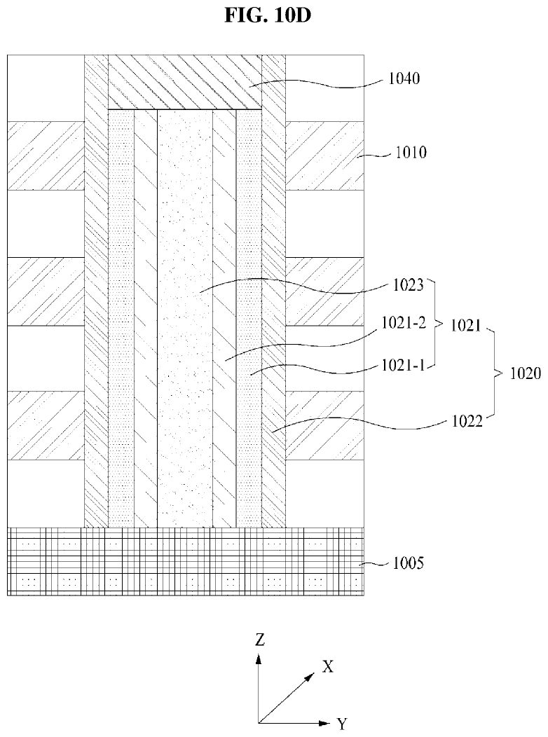

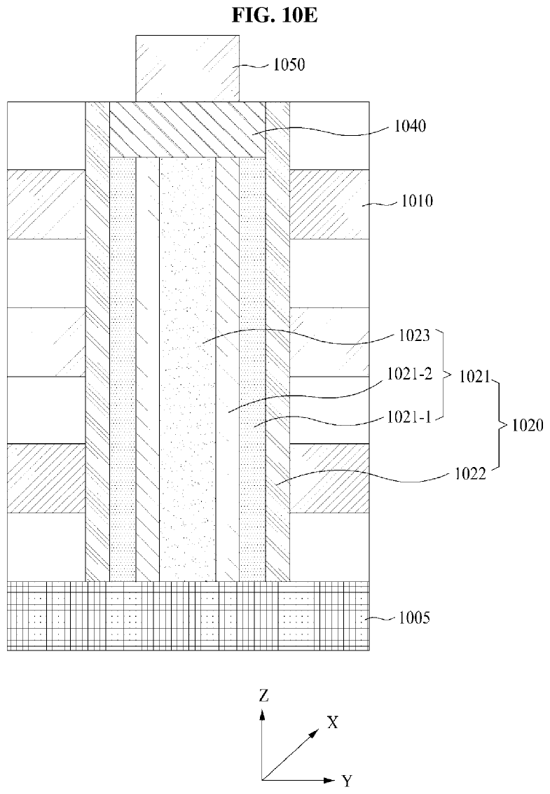

FIG. 9 is a flowchart illustrating a method of manufacturing the three-dimensional flash memory according to the embodiment, and FIGS. 10A to 10E are side cross-sectional views illustrating the three-dimensional flash memory to describe the manufacturing method illustrated in FIG. 9.

Hereinafter, the manufacturing method, which will be described below, is based on the premise that the manufacturing method is performed by an automated and mechanized manufacturing system, and the three-dimensional flash memory completely manufactured through the manufacturing method may have the structure described with reference to FIG. 3.

Referring to FIG. 9, in operation S910, a manufacturing system according to the embodiment may prepare a semiconductor structure 1000 as in FIG. 10A.

Here, the semiconductor structure 1000 may include a plurality of word lines 1010 extending on a substrate 1005 in a horizontal direction and sequentially stacked and at least one string 1020 passing through the plurality of word lines 1010 and extending on the substrate 1005 in a vertical direction. The at least one string 1020 may include a channel layer 1021 extending in a vertical direction and a charge storage layer 1022 extending in a vertical direction to surround the channel layer 1021.

In particular, the channel layer 1021 is implemented in a double structure including an outer first channel layer 1021-1 and a second channel layer 1021-2 formed on an inner wall of the first channel layer 1021-1. Thus, a heterojunction may be formed as a junction between the first channel layer 1021-1 and the second channel layer 1021-2. Accordingly, a quantum well is implemented by the heterojunction, and thus an electron mobility in the junction between the first channel layer 1021-1 and the second channel layer 1021-2 may be improved.

That is, in operation S910, while preparing the semiconductor structure 1000, the manufacturing system may form the heterojunction as the junction between the first channel layer 1021-1 and the second channel layer 1021-2 and implement the quantum well by the heterojunction to improve the electron mobility in the junction between the first channel layer 1021-1 and the second channel layer 1021-2.

In this way, the manufacturing system may form the first channel layer 1021-1 and the second channel layer 1021-2 of a metal oxide so that the heterojunction is formed as the junction between the first channel layer 1021-1 and the second channel layer 1021-2. As an example, the manufacturing system may form the first channel layer 1021-1 and the second channel layer 1021-2 of a metal oxide including at least one of In, Zn, or Ga or a metal oxide including a group 4 semiconductor material.

In this case, the manufacturing system may form the first channel layer 1021-1 and the second channel layer 1021-2 of different materials among metal oxides. For example, the manufacturing system may form the first channel layer 1021-1 of an IGZO material and may form the second channel layer 1021-2 of a ZnO material.

Further, in the semiconductor structure 1000, a buried film 1023 may be formed inside the channel layer 1021. As an example, the oxide buried film 1023 may be formed in an inner space of the second channel layer 1021-2.

Next, in operation S920, the manufacturing system etches an upper end portion of the at least one string 1020 as in FIG. 10B and then fills an etched space 1030 with the same material 1031 as that of the first channel layer 1021-1 (or a capping material unrelated to the first channel layer 1021-1) as in FIG. 10C. The manufacturing system performs N+ doping on the upper end portion of the at least one string 1020 as in FIG. 10D and thus forms a N+ doped part 1040 at an upper end of the at least one string 1020.

Thereafter, in operation S930, the manufacturing system may generate at least one wiring line 1050 in contact with the N+ doped part 1040.

As described above, although the embodiments have been described with reference to the limited embodiments and the limited drawings, various modifications and changes may be made based on the above description by those skilled in the art. For example, even though the described technologies are performed in an order different from the described method, and/or the described components such as a system, a structure, a device, and a circuit are coupled or combined in a form different from the described method or are replaced or substituted by other components or equivalents, appropriate results may be achieved.

Therefore, other implementations, other embodiments, and those equivalent to the appended claims also belong to the scope of the appended claims.

1. A three-dimensional flash memory comprising:
a plurality of word lines extending on a substrate in a horizontal direction and sequentially stacked; and
at least one cell string passing through the plurality of word lines and extending on the substrate in a vertical direction, the at least one cell string including a channel layer extending in the vertical direction and a charge storage layer formed to surround the channel layer,
wherein the channel layer has a double structure including a first channel layer for improving an electron mobility in an inversion area that is a contact interface with the charge storage layer while the first channel layer is formed in contact with the charge storage layer and a second channel layer formed on an inner wall of the first channel layer.

2. The three-dimensional flash memory of claim 1, wherein the first channel layer is formed of a material having a higher electron mobility than that of the second channel layer or a higher electron mobility than a threshold value to improve the electron mobility in the inversion area that is a contact interface with the charge storage layer.

3. The three-dimensional flash memory of claim 2, wherein the first channel layer is formed of any one of a polycrystalline group 3-5 compound (poly 3-5) or polycrystalline silicon germanium (poly Si—Ge).

4. The three-dimensional flash memory of claim 1, wherein the second channel layer is used as a protection layer or an electron transfer assist layer for the first channel layer.

5. The three-dimensional flash memory of claim 4, wherein the second channel layer is formed of a material having more excellent durability and thermal performance than those of the first channel layer.

6. The three-dimensional flash memory of claim 5, wherein the second channel layer is formed of polycrystalline silicon (Poly Si).

7. A method of manufacturing a three-dimensional flash memory, the method comprising:
preparing a semiconductor structure including a plurality of word lines extending on a substrate in a horizontal direction and sequentially stacked and at least one hole passing through the plurality of word lines and extending on the substrate in a vertical direction;
forming a charge storage layer including an inner hole in the at least one hole of the semiconductor structure; and
extending a channel layer having a double structure in the vertical direction inside the inner hole,
wherein the extending of the channel layer includes:
forming a first channel layer for improving an electron mobility in an inversion area that is a contact interface with the charge storage layer such that the first channel layer is in contact with the charge storage layer; and
forming a second channel layer in an inner wall of the first channel layer.

8. A method of manufacturing a three-dimensional flash memory, the method comprising:
preparing a semiconductor structure including a plurality of sacrificial layers extending on a substrate in a horizontal direction and sequentially stacked and at least one hole passing through the plurality of sacrificial layers and extending on the substrate in a vertical direction;
forming a charge storage layer including an inner hole in the at least one hole of the semiconductor structure;
extending a channel layer having a double structure in the vertical direction inside the inner hole;
removing the plurality of sacrificial layers; and
forming a plurality of word lines in spaces from which the plurality of sacrificial layers are removed,
wherein the extending of the channel layer includes:
forming a first channel layer for improving an electron mobility in an inversion area that is a contact interface with the charge storage layer such that the first channel layer is in contact with the charge storage layer; and
forming a second channel layer in an inner wall of the first channel layer.

9. A three-dimensional flash memory comprising:
a plurality of word lines extending on a substrate in a horizontal direction and sequentially stacked; and
at least one string passing through the plurality of word lines and extending on the substrate in a vertical direction, the at least one string including a channel layer extending in the vertical direction and a charge storage layer formed to surround the channel layer,
wherein while the channel layer has a double structure including an outer first channel layer and a second channel layer formed in an inner wall of the first channel layer, a heterojunction is formed as a junction between the first channel layer and the second channel layer.

10. The three-dimensional flash memory of claim 9, wherein the first channel layer and the second channel layer are formed of a metal oxide so that the heterojunction is formed as the junction between the first channel layer and the second channel layer.

11. The three-dimensional flash memory of claim 10, wherein the first channel layer and the second channel layer are formed of a metal oxide including at least one of In, Zn, or Ga or a metal oxide including a group 4 semiconductor material.

12. The three-dimensional flash memory of claim 10, wherein the first channel layer and the second channel layer are formed of different materials among the metal oxides.

13. The three-dimensional flash memory of claim 9, wherein the three-dimensional flash memory implements a quantum well through the heterojunction to improve an electron mobility in the junction between the first channel layer and the second channel layer.

14. A method of manufacturing a three-dimensional flash memory, the method comprising:
preparing a semiconductor structure including a plurality of word lines extending on a substrate in a horizontal direction and sequentially stacked, and at least one string passing through the plurality of word lines and extending on the substrate in a vertical direction, the at least one string including a channel layer extending in the vertical direction and a charge storage layer formed to surround the channel layer;
forming an N+ doped part at an upper end of the at least one string; and
generating at least one wiring line in contact with the N+ doped part,
wherein the preparing of the semiconductor structure includes:
implementing the channel layer through a double structure including an outer first channel layer and a second channel layer formed on an inner wall of the first channel layer so that a heterojunction is formed as a junction between the first channel layer and the second channel layer.
